(19) United States
(12) Patent Application Publication
(10) Pub. No.: US 2025/0158001 A1
(43) Pub. Date: May 15, 2025

(54) CHIP STRUCTURE AND SEMICONDUCTOR PACKAGE INCLUDING THE SAME

(71) Applicant: Samsung Electronics Co., Ltd., Suwon-si (KR)

(72) Inventors: Hyunsoo Chung, Suwon-si (KR); Kwangsoo Kim, Suwon-si (KR); Chiwoo Lee, Suwon-si (KR)

(21) Appl. No.: 18/780,621

(22) Filed: Jul. 23, 2024

(30) Foreign Application Priority Data
Nov. 14, 2023 (KR) 10-2023-0157701

(51) Int. Cl. H01L 25/18; H01L 23/00; H01L 23/31; H01L 23/48

(52) U.S. Cl. CPC H01L 25/18; H01L 23/3135; H01L 23/481; H01L 24/16; H01L 2224/16148; H01L 2224/16227; H01L 2224/16238; H01L 2924/1431; H01L 2924/1436

(57) ABSTRACT

A chip structure including a semiconductor chip, a photonic integrated circuit chip spaced apart from the semiconductor chip in a horizontal direction, an electronic integrated circuit chip on the semiconductor chip and the photonic integrated circuit chip, a first molding layer surrounding the semiconductor chip and the photonic integrated circuit chip, and a second molding layer on the semiconductor chip, the photonic integrated circuit chip, and the first molding layer and surrounding the electronic integrated circuit chip. A portion of the electronic integrated circuit chip overlaps the photonic integrated circuit chip in a vertical direction, and another portion of the electronic integrated circuit chip overlaps the semiconductor chip in the vertical direction.

### CROSS-REFERENCE TO RELATED APPLICATION

This application is based on and claims priority under 35 U.S.C. § 119 to Korean Patent Application No. 10-2023-0157701, filed on Nov. 14, 2023, in the Korean Intellectual Property Office, the disclosure of which is incorporated by reference herein in its entirety.

### BACKGROUND

Aspects of the inventive concept relate to a semiconductor package and a method of manufacturing the same, and more particularly, to a chip structure including a photonic integrated circuit chip and a semiconductor package including the chip structure.

The benefits of semiconductor packages have been largely used to improve the function of an electronic device and integrate components therein. A semiconductor package may allow various integrated circuits, such as memory chips and logic chips, to be mounted on a package substrate. Recently, in an environment in which data traffic increases in data centers and communication infrastructures, research on a semiconductor package including a photonic integrated circuit has been conducted.

### SUMMARY

Aspects of the inventive concept provide a semiconductor package with a shortened signal transfer distance.

Aspects of the inventive concept also provide a semiconductor package that is easy to test.

In addition, the problems to be solved by the technical idea of the inventive concept are not limited to the problems mentioned above, and other problems could be clearly understood by those of ordinary skill in the art from the description below.

According to an aspect of the inventive concept, there is provided a chip structure including a semiconductor chip, a photonic integrated circuit chip spaced apart from the semiconductor chip in a horizontal direction, an electronic integrated circuit chip on the semiconductor chip and the photonic integrated circuit chip, a first molding layer surrounding the semiconductor chip and the photonic integrated circuit chip, and a second molding layer on the semiconductor chip, the photonic integrated circuit chip, and the first molding layer and surrounding the electronic integrated circuit chip, wherein a portion of the electronic integrated circuit chip overlaps the photonic integrated circuit chip in a vertical direction, and another portion of the electronic integrated circuit chip overlaps the semiconductor chip in the vertical direction.

According to another aspect of the inventive concept, there is provided a semiconductor package including a package substrate, at least one stacked structure on the package substrate, and a chip structure on the package substrate and spaced apart from the at least one stacked structure in a horizontal direction, wherein the chip structure includes a semiconductor chip on the package substrate, a photonic integrated circuit chip on the package substrate and spaced apart from the semiconductor chip in the horizontal direction, an electronic integrated circuit chip on the semiconductor chip and the photonic integrated circuit chip, a first molding layer surrounding the semiconductor chip and the photonic integrated circuit chip, and a second molding layer on the first molding layer and surrounding the electronic integrated circuit chip, wherein a portion of the electronic integrated circuit chip overlaps the photonic integrated circuit chip in a vertical direction, and another portion of the electronic integrated circuit chip overlaps the semiconductor chip in the vertical direction.

According to another aspect of the inventive concept, there is provided a semiconductor package including a package substrate, a plurality of stacked structures on the package substrate, a chip structure on the package substrate and spaced apart from the plurality of stacked structures in a horizontal direction, and a third molding layer on the package substrate and surrounding the plurality of stacked structures and the chip structure, wherein the chip structure includes a semiconductor chip on the package substrate and including a first through via, a photonic integrated circuit chip on the package substrate, spaced apart from the semiconductor chip in the horizontal direction, and including a second through via, an electronic integrated circuit chip on the semiconductor chip and the photonic integrated circuit chip, a dummy chip on the semiconductor chip, a first molding layer surrounding the semiconductor chip and the photonic integrated circuit chip, and a second molding layer on the first molding layer and surrounding the electronic integrated circuit chip and the dummy chip, wherein a portion of the electronic integrated circuit chip overlaps the second through via of the photonic integrated circuit chip in a vertical direction, and another portion of the electronic integrated circuit chip overlaps the first through via of the semiconductor chip in the vertical direction.

### BRIEF DESCRIPTION OF THE DRAWINGS

Embodiments of the inventive concept will be more clearly understood from the following detailed description taken in conjunction with the accompanying drawings in which:

FIG. 1 is a top view schematically illustrating a semiconductor package according to an embodiment;

FIG. 2 is a cross-sectional view schematically illustrating the semiconductor package of FIG. 1, taken along line A-A′ of FIG. 1;

FIG. 3 is a magnified cross-sectional view schematically illustrating a chip structure of the semiconductor package of FIG. 2;

FIG. 4 is a magnified cross-sectional view schematically illustrating a chip structure of a semiconductor package according to an embodiment;

FIG. 5 is a magnified cross-sectional view schematically illustrating a chip structure of a semiconductor package according to an embodiment;

FIG. 6 is a top view schematically illustrating a semiconductor package according to an embodiment;

FIG. 7 is a cross-sectional view schematically illustrating the semiconductor package of FIG. 6, taken along line B-B′ of FIG. 6; and

FIGS. 8 to 14 are cross-sectional views illustrating, in a process order, a method of manufacturing a semiconductor package according to an embodiment.

### DETAILED DESCRIPTION OF THE EMBODIMENTS

Aspects of the inventive concept may allow various kinds of change or modification and various changes in form, and specific embodiments will be illustrated in drawings and described in detail in the specification. However, the specific embodiments do not limit aspects of the inventive concept to a specific disclosing form.

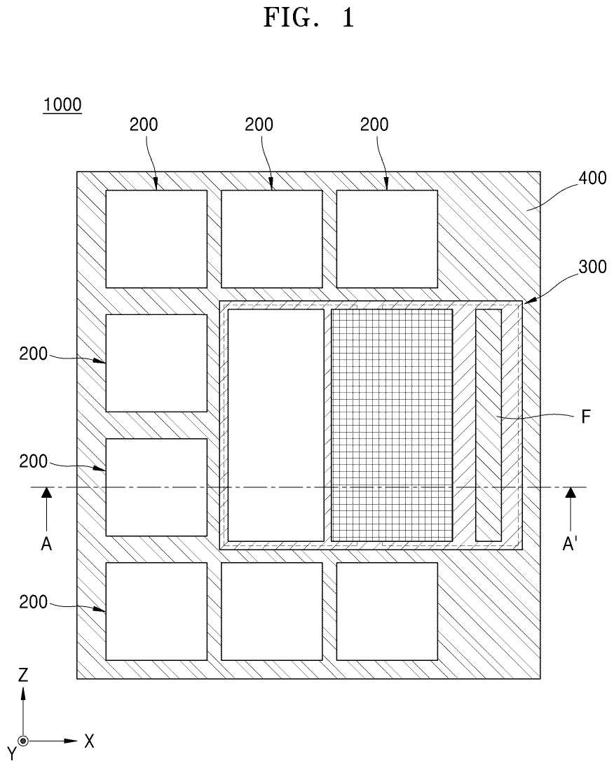

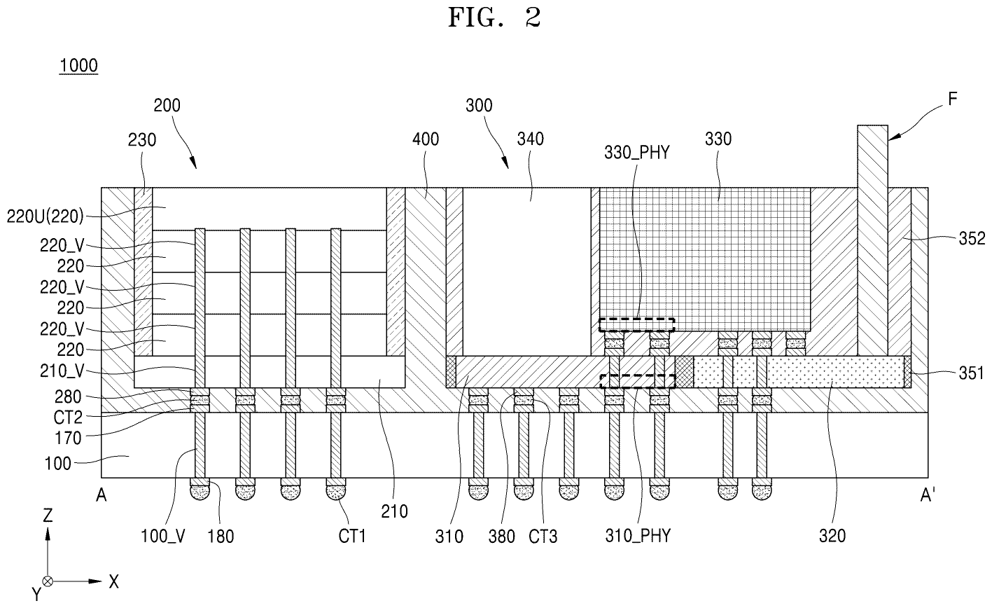

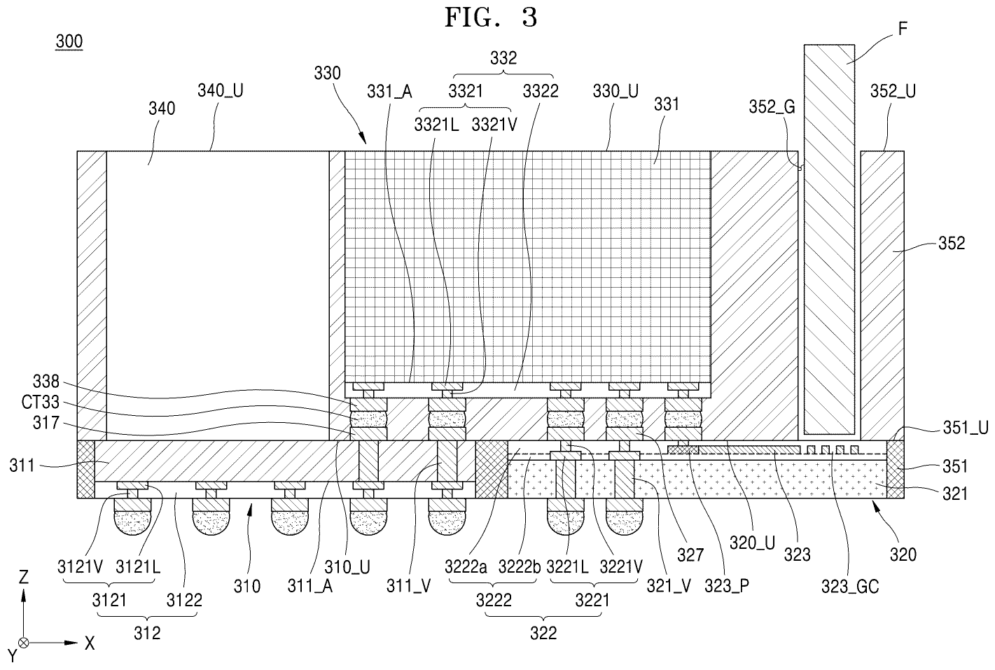

FIG. 1 is a top view schematically illustrating a semiconductor package 1000 according to an embodiment. FIG. 2 is a cross-sectional view schematically illustrating the semiconductor package 1000 of FIG. 1, taken along line A-A′ of FIG. 1. FIG. 3 is a magnified cross-sectional view schematically illustrating a chip structure 300 of the semiconductor package 1000 of FIG. 2.

Referring to FIGS. 1 to 3, the semiconductor package 1000 may include a package substrate 100, a stacked structure 200, and the chip structure 300. As further illustrated in FIGS. 1 to 3, a plurality of stacked structures 200 may be included in the semiconductor package 1000. Accordingly, the semiconductor package 1000 may include at least one stacked structure 200.

Hereinafter, unless particularly defined, a direction parallel to the upper surface of the package substrate 100 is defined as a first horizontal direction (an X direction), a direction perpendicular to the upper surface of the package substrate 100 is defined as the vertical direction (a Z direction), and a direction perpendicular to the first horizontal direction (the X direction) and the vertical direction (the Z direction) is defined as a second horizontal direction (a Y direction). A direction in which the first horizontal direction (the X direction) and the second horizontal direction (the Y direction) are combined is defined as a horizontal direction.

The package substrate 100 may be an interposer including a substrate and through vias 100_V through the substrate. For example, the package substrate 100 may be a glass interposer, wherein the substrate includes glass and a through via 100_V is a through glass via (TGV). However, the package substrate 100 is not limited thereto and may be a silicon (Si) interposer, wherein the substrate includes Si and the through via 100_V is a through silicon via (TSV).

In some embodiments, the package substrate 100 may be a redistribution structure including a redistribution pattern and a redistribution insulating layer surrounding the redistribution pattern.

The redistribution insulating layer may include an insulating material, e.g., a photo imageable dielectric (PID) resin. In some embodiments, the redistribution insulating layer may further include an inorganic filler. In some embodiments, the redistribution insulating layer may have a multi-layer structure with the redistribution pattern arranged in each layer.

The redistribution pattern may include a redistribution line pattern extending in the horizontal direction and a redistribution via pattern extending in the vertical direction (the Z direction) from the redistribution line pattern. The redistribution line pattern may be arranged on at least one surface of the upper and lower surfaces of the redistribution insulating layer or inside the redistribution insulating layer. The redistribution via pattern may be connected to a portion of the redistribution line pattern by penetrating the redistribution insulating layer.

The redistribution pattern may include a conductive material, e.g., copper (Cu), aluminum (Al), silver (Ag), tin (Sn), gold (Au), nickel (Ni), lead (Pb), titanium (Ti), or an alloy thereof.

In some embodiments, the package substrate 100 may be a printed circuit board (PCB) including a core insulating layer including at least one material selected from among a phenol resin, an epoxy resin, and polyimide.

The package substrate 100 may include upper pads 170 located on the upper surface of the package substrate 100 and lower pads 180 located on the lower surface of the package substrate 100. The upper pads 170 may be electrically connected the lower pads 180 by corresponding through vias 100_V, respectively. However, the upper pads 170 and the lower pads 180 are not limited thereto, and the upper pads 170 may be electrically connected the lower pads 180 by the redistribution pattern or an internal wiring. In some embodiments, each of the upper pads 170 and the lower pads 180 may include Cu, Ni, stainless steel, or beryllium copper.

External connection terminals CT1 may be attached to the lower pads 180. The external connection terminals CT1 may electrically and physically connect the package substrate 100 to an external device on which the package substrate 100 is mounted. The external connection terminals CT1 may be formed by, for example, a solder ball or a solder bump.

However, the present embodiment is not limited thereto, and the package substrate 100 may be mounted in a socket formed on an external device. That is, the package substrate 100 may be electrically and physically connected to an external device without the external connection terminals CT1.

At least one stacked structure 200 may be located on the package substrate 100. A plurality of stacked structures 200 may be located on the package substrate 100 and may be spaced apart from each other in the horizontal direction. For example, the plurality of stacked structures 200 may be arranged to surround the chip structure 300.

In some embodiments, the area of each stacked structure 200 may be less than the area of the chip structure 300. In some embodiments, a plurality of stacked structures 200 may be arranged on the package substrate 100 in a U shape. The plurality of stacked structures 200 may be arranged to surround the chip structure 300. For example, the chip structure 300 may be located in a region surrounded by the plurality of stacked structures 200.

Each stacked structure 200 may include a buffer chip 210, a plurality of core chips 220, and a fourth molding layer 230. The buffer chip 210 may be located on the package substrate 100, and the plurality of core chips 220 may be stacked on the buffer chip 210 in the vertical direction (the Z direction).

Each of the buffer chip 210 and the plurality of core chips 220 may include a semiconductor material, e.g., Si or germanium (Ge). Alternatively, each of the plurality of core chips 220 may include a compound semiconductor material, such as silicon carbide (SiC), gallium arsenide (GaAs), indium arsenide (InAs), or indium phosphide (InP).

Each of the buffer chip 210 and the plurality of core chips 220 may include an active surface and an inactive surface opposite to the active surface. A semiconductor device including a plurality of individual devices of various types may be formed on the active surface of each of the buffer chip 210 and the plurality of core chips 220. Each of the buffer chip 210 and the plurality of core chips 220 may include an impurity-doped well that is a conductive region. Each of the buffer chip 210 and the plurality of core chips 220 may have various device isolation structures, such as a shallow trench isolation (STI).

The plurality of individual devices of the buffer chip 210 may include various microelectronic devices, e.g., a metal-oxide-semiconductor field effect transistor (MOSFET), such as a complementary metal-oxide-semiconductor (CMOS) transistor, a system large scale integration (LSI), an image sensor, such as a CMOS imaging sensor (CIS), a micro-electro-mechanical system (MEMS), an active device, a passive device, and the like.

The plurality of individual devices of each of the plurality of core chips 220 may include a memory cell. For example, the memory cell may be a nonvolatile memory cell, such as flash memory, phase-change random access memory (PRAM), magnetoresistive random access memory (MRAM), ferroelectric random access memory (FeRAM), or resistive random access memory (RRAM). In some embodiments, the memory cell may be a volatile memory cell, such as dynamic random access memory (DRAM) or static random access memory (SRAM).

The plurality of individual devices of the buffer chip 210 may be electrically connected to the conductive region of the buffer chip 210, and the plurality of individual devices of each of the plurality of core chips 220 may be electrically connected to the conductive region of each of the plurality of core chips 220. For example, each of the buffer chip 210 and the plurality of core chips 220 may further include a conductive wiring or a conductive plug which electrically connects the plurality of individual devices to the conductive region. In addition, each of the plurality of individual devices may be electrically isolated from a neighboring different individual device by an insulating layer.

In some embodiments, the buffer chip 210 may be a semiconductor chip which includes a serial-parallel conversion circuit and controls the plurality of core chips 220, and the plurality of core chips 220 may be memory chips including memory cells. For example, a stacked structure 200 including the buffer chip 210 and the plurality of core chips 220 may be a high bandwidth memory (HBM), wherein the buffer chip 210 may be referred to as an HBM controller die, and each of the plurality of core chips 220 may be referred to as a DRAM die.

In some embodiments, a core chip 220 at the top among the plurality of core chips 220 may be referred to as a top core chip 220U. Although FIG. 2 shows that the stacked structure 200 includes four core chips 220 stacked therein, the number of core chips 220 included in the stacked structure 200 is not limited thereto.

In some embodiments, each of the core chips 220 except for the top core chip 220U among the plurality of core chips 220 may further include through vias 220_V extending inward from the upper surface of each core chip 220. The through vias 220_V of each core chip 220 may be electrically connected to the conductive region of the core chip 220. However, the plurality of core chips 220 are not limited thereto, and the top core chip 220U may include the through vias 220_V.

Each of the plurality of core chips 220 may be electrically connected to an adjacent core chip 220 or the buffer chip 210 through the through vias 220_V. Accordingly, the plurality of core chips 220 may be electrically connected to the package substrate 100 through the through vias 220_V. For example, the conductive region of the top core chip 220U may be electrically connected to the package substrate 100 through the through vias 220_V of the core chips 220 stacked beneath the top core chip 220U.

In some embodiments, the thickness, i.e., the length in the vertical direction (the Z direction), of each of the plurality of core chips 220 may be about 20 μm to about 80 μm. The thicknesses of the plurality of core chips 220 may have substantially the same values.

In some embodiments, lower pads 280 may be located beneath the lower surface of the buffer chip 210. The lower pads 280 of the buffer chip 210 may be electrically connected to through vias 210_V or the conductive region of the buffer chip 210.

The lower pads 280 of the buffer chip 210 may be electrically connected to corresponding upper pads 170 of the package substrate 100 by connection terminals CT2, respectively. However, the present embodiment is not limited thereto, and the lower pads 280 of the buffer chip 210 may be electrically connected to the corresponding upper pads 170 of the package substrate 100 by an anisotropic conductive film (ACF), a non-conductive film (NCF), direct bonding, or hybrid bonding.

The fourth molding layer 230 may surround the plurality of core chips 220 on the buffer chip 210. For example, the upper surface of the fourth molding layer 230 may be coplanar with the upper surface of the top core chip 220U. Accordingly, the upper surface of the top core chip 220U may be exposed to the outside.

The chip structure 300 may be located on the package substrate 100 and spaced apart from the stacked structure 200 in the horizontal direction. In some embodiments, a semiconductor chip 310 of the chip structure 300 may be located in a central region of the package substrate 100. The chip structure 300 may be electrically connected to the stacked structure 200 and transmit and receive an electrical signal to and from the stacked structure 200.

In some embodiments, lower pads 380 may be located on the lower surface of the chip structure 300. The lower pads 380 of the chip structure 300 may be electrically connected to the semiconductor chip 310 and a photonic integrated circuit (PIC) chip 320.

The lower pads 380 of the chip structure 300 may be electrically connected to corresponding upper pads 170 of the package substrate 100 by connection terminals CT3, respectively. However, the present embodiment is not limited thereto, and the lower pads 380 of the chip structure 300 may be electrically connected to the corresponding upper pads 170 of the package substrate 100 by an ACF, an NCF, direct bonding, or hybrid bonding.

The chip structure 300 is described in more detail with reference to FIG. 3.

The chip structure 300 may include the semiconductor chip 310, the PIC chip 320, an electronic integrated circuit (EIC) chip 330, a first molding layer 351, and a second molding layer 352. In some embodiments, the semiconductor chip 310 may include an application specific integrated circuit (ASIC).

The semiconductor chip 310 may be located on the package substrate 100 and include a first substrate 311, a first wiring structure 312, and first through vias 311_V. In some embodiments, upper pads 317 may be located on the upper surface of the semiconductor chip 310. The upper pads 317 may be electrically connected to the first through vias 311_V, respectively.

The first substrate 311 may include an active surface 311_A and an inactive surface opposite to the active surface 311_A. The first wiring structure 312 may be located on the active surface 311_A of the first substrate 311. In some embodiments, the first through vias 311_V may be electrically connected to a plurality of individual devices on the first wiring structure 312 and/or the active surface 311_A.

In some embodiments, the semiconductor chip 310 may be mounted on the package substrate 100 such that the active surface 311_A of the first substrate 311 faces the package substrate 100. For example, the semiconductor chip 310 may be disposed on the package substrate 100 in a face down manner.

In some embodiments, the plurality of individual devices of various types may be located on the active surface 311_A of the first substrate 311. For example, the plurality of individual devices may include various microelectronic devices, e.g., a MOSFET, such as a CMOS transistor, a system LSI, an image sensor, such as a CIS, a MEMS, an active device, a passive device, and the like.

The first wiring structure 312 may include first wiring patterns 3121 and a first wiring insulating layer 3122 surrounding the first wiring patterns 3121. A first wiring pattern 3121 may include a first wiring line 3121L extending in the horizontal direction and a first wiring via 3121V extending in the vertical direction (the Z direction) from the first wiring line 3121L. Corresponding first wiring patterns 3121 may be electrically connected to the first through vias 311_V, respectively.

The PIC chip 320 may be located on the package substrate 100. The PIC chip 320 may be spaced apart from the semiconductor chip 310 in the horizontal direction. For example, the lower surface of the PIC chip 320 may be coplanar with the lower surface of the semiconductor chip 310.

In some embodiments, the thicknesses, i.e., the lengths in the vertical direction (the Z direction), of the PIC chip 320 and the semiconductor chip 310 may be the same as each other. The upper surface of the PIC chip 320 may be coplanar with the upper surface of the semiconductor chip 310.

The PIC chip 320 may include a second substrate 321, a second wiring structure 322, and a waveguide 323. For example, the second wiring structure 322 and the waveguide 323 may be located on the upper surface of the second substrate 321. For example, the second substrate 321 may include second through vias 321_V extending from the upper surface of the second substrate 321 to the lower surface thereof. The second through vias 321_V may be electrically connected to the second wiring patterns 3221 of the second wiring structure 322.

In some embodiments, the second substrate 321 may include a semiconductor material, such as Si. Alternatively, the second substrate 321 may include a semiconductor material, such as Ge.

The second wiring structure 322 may include the second wiring patterns 3221 and a second wiring insulating layer 3222 surrounding the second wiring patterns 3221. A second wiring pattern 3221 may include a second wiring line 3221L extending in the horizontal direction and a second wiring via 3221V extending in the vertical direction (the Z direction) from the second wiring line 3221L. The second wiring patterns 3221 may be electrically connected to the second through vias 321_V, respectively.

The second wiring insulating layer 3222 may be divided into a lower wiring insulating layer 3222b and an upper wiring insulating layer 3222a. In some embodiments, the lower wiring insulating layer 3222b may be an oxide layer including Si oxide or the like. The upper wiring insulating layer 3222a may be a dielectric layer formed by one or more layers including Si oxide, Si nitride, or a combination thereof. In some embodiments, the lower wiring insulating layer 3222b may include the same material as the upper wiring insulating layer 3222a.

The waveguide 323 is a patterned Si layer and may extend in the horizontal direction on the lower wiring insulating layer 3222b. For example, the waveguide 323 may be buried in the second wiring insulating layer 3222. For example, the waveguide 323 may be located on the lower wiring insulating layer 3222b and covered by the upper wiring insulating layer 3222a. In some embodiments, the waveguide 323 may be an Si waveguide including Si, and the second wiring insulating layer 3222 may be a buried oxide (BOX) layer. In some embodiments, the waveguide 323 is not limited thereto and may be covered by an oxide layer distinguished from the second wiring insulating layer 3222.

The waveguide 323 may be connected to an optical component 323_P. The optical component 323_P may convert an optical signal into an electrical signal and convert an electrical signal into an optical signal. In some embodiments, the optical component 323_P may include a photodetector, a light-emitting diode, and a modulator.

In a process in which an optical signal is input to the chip structure 300, the photodetector may detect the optical signal input to the PIC chip 320. The PIC chip 320 may detect the input optical signal through the photodetector and convert the input optical signal into an electrical signal.

In a process in which the chip structure 300 outputs an optical signal, the EIC chip 330 may transmit an electrical signal to the modulator. The modulator may convert the electrical signal into an optical signal by inputting a signal corresponding to the received electrical signal to light emitted by the light-emitting diode.

The PIC chip 320 may further include upper pads 327. The upper pads 327 are located on the upper surface of the second wiring structure 322 and may be electrically connected to corresponding second wiring patterns 3221.

In some embodiments, the active surface 311_A of the first substrate 311 of the semiconductor chip 310 may face the package substrate 100, and the waveguide 323 of the PIC chip 320 may face the EIC chip 330. For example, the active surface 311_A of the first substrate 311 may face the bottom of the semiconductor chip 310, and the waveguide 323 of the PIC chip 320 may face the top of the PIC chip 320.

In some embodiments, the vertical level of the active surface 311_A of the first substrate 311 may differ from the vertical level of the waveguide 323 of the PIC chip 320. The vertical level of the active surface 311_A of the first substrate 311 may be lower than the vertical level of the waveguide 323 of the PIC chip 320. As used herein, a vertical level indicates a distance separated from the lower surface of the package substrate 100.

The first molding layer 351 may be located above the package substrate 100 and surround the semiconductor chip 310 and the PIC chip 320. For example, the lower surface of the first molding layer 351, the lower surface of the semiconductor chip 310, and the lower surface of the PIC chip 320 may be coplanar with each other. In some embodiments, an upper surface 351_U of the first molding layer 351, an upper surface 310_U of the semiconductor chip 310, and an upper surface 320_U of the PIC chip 320 may be coplanar with each other. The first molding layer 351 may protect the semiconductor chip 310 and the PIC chip 320 from the outside.

The EIC chip 330 may be located on the semiconductor chip 310 and the PIC chip 320. For example, the lower surface of the EIC chip 330 may face the semiconductor chip 310, the PIC chip 320, and the first molding layer 351.

For example, a portion of the EIC chip 330 may overlap the semiconductor chip 310 in the vertical direction (the Z direction), and another portion of the EIC chip 330 may overlap the PIC chip 320 in the vertical direction (the Z direction). In some embodiments, the EIC chip 330 may be in contact with both the semiconductor chip 310 and the PIC chip 320. In some embodiments, a physical layer 330_PHY of the EIC chip 330 may overlap a physical layer 310_PHY of the semiconductor chip 310 in the vertical direction (the Z direction).

In some embodiments, the EIC chip 330 may overlap the first through vias 311_V of the semiconductor chip 310 and the second through vias 321_V of the PIC chip 320 in the vertical direction (the Z direction). For example, the first through vias 311_V and the second through vias 321_V may be located under the EIC chip 330. In some embodiments, the second through vias 321_V may supply power to the EIC chip 330, and the first through vias 311_V may connect the physical layer 330_PHY of the EIC chip 330 to the physical layer 310_PHY of the semiconductor chip 310.

The EIC chip 330 may include a third substrate 331 and a third wiring structure 332. The third substrate 331 of the EIC chip 330 may include an active surface 331_A and an inactive surface opposite to the active surface 331_A. The third wiring structure 332 may be formed on the active surface 331_A of the third substrate 331.

The third substrate 331 may include a semiconductor material, such as Si. Alternatively, the third substrate 331 may include a semiconductor material, such as Ge.

In some embodiments, the EIC chip 330 may include a plurality of individual devices used to interface with the PIC chip 320. The plurality of individual devices of the EIC chip 330 may be located on the active surface 331_A of the third substrate 331. For example, the EIC chip 330 may include CMOS drivers, transimpedance amplifiers, and the like to perform functions, such as control of high frequency signaling of the PIC chip 320.

The third wiring structure 332 may include third wiring patterns 3321 and a third wiring insulating layer 3322 surrounding the third wiring patterns 3321. A third wiring pattern 3321 may include a third wiring line 3321L extending in the horizontal direction and a third wiring via 3321V extending in the vertical direction (the Z direction) from the third wiring line 3321L. The third wiring patterns 3321 may be electrically connected to the plurality of individual devices.

In some embodiments, the EIC chip 330 may be disposed on the PIC chip 320 such that the active surface 331_A of the third substrate 331 faces the PIC chip 320. For example, the EIC chip 330 may be disposed on the PIC chip 320 in the face down manner.

The EIC chip 330 may further include lower pads 338. The lower pads 338 are located on the lower surface of the third wiring structure 332 and may be electrically connected to the third wiring patterns 3321, respectively.

The lower pads 338 of the EIC chip 330 may be electrically connected to the upper pads 327 of the PIC chip 320 and the upper pads 317 of the semiconductor chip 310 by connection terminals CT33, respectively. However, the present embodiment is not limited thereto, and the lower pads 338 of the EIC chip 330 may be electrically connected to the upper pads 327 of the PIC chip 320 and the upper pads 317 of the semiconductor chip 310 by an ACF, an NCF, direct bonding, or hybrid bonding.

In some embodiments, the chip structure 300 may further include a dummy chip 340. The dummy chip 340 may be located on the semiconductor chip 310. For example, the dummy chip 340 may be located in a region of the upper surface of the semiconductor chip 310, in which the EIC chip 330 is not located. The dummy chip 340 may be helpful in discharging heat generated by the semiconductor chip 310. For example, the dummy chip 340 may prevent the top of the semiconductor chip 310 from being covered by the second molding layer 352, thereby being helpful in discharging heat generated by the semiconductor chip 310 to the outside.

The dummy chip 340 may include a semiconductor material, e.g., Si. In some embodiments, the dummy chip 340 may include only a semiconductor material. For example, the dummy chip 340 may be a portion of a bare wafer.

The second molding layer 352 may be located on the semiconductor chip 310, the PIC chip 320, and the first molding layer 351. The second molding layer 352 may surround the EIC chip 330. In some embodiments, when the chip structure 300 further includes the dummy chip 340, the second molding layer 352 may surround the EIC chip 330 and the dummy chip 340.

In some embodiments, an upper surface 352_U of the second molding layer 352 may be coplanar with an upper surface 330_U of the EIC chip 330. The upper surface 330_U of the EIC chip 330 may be exposed to the outside. The upper surface 352_U of the second molding layer 352 may be coplanar with an upper surface 340_U of the dummy chip 340. The upper surface 340_U of the dummy chip 340 may be exposed to the outside.

In some embodiments, each of the first molding layer 351 and the second molding layer 352 may include an epoxy resin, a polyimide resin, or the like. Each of the first molding layer 351 and the second molding layer 352 may include, for example, an epoxy molding compound (EMC). For example, the first molding layer 351 may include the same material as the second molding layer 352.

In some embodiments, a boundary surface may be present between the first molding layer 351 and the second molding layer 352. For example, the boundary surface may be present between the first molding layer 351 and the second molding layer 352 because a curing time of the first molding layer 351 differs from a curing time of the second molding layer 352. For example, the boundary surface may be present between the first molding layer 351 and the second molding layer 352 even though the first molding layer 351 includes the same material as the second molding layer 352.

In some embodiments, the second molding layer 352 may further include an opening 352_G. The opening 352_G may extend inward from the upper surface of the second molding layer 352. The opening 352_G may be spaced apart from the EIC chip 330 in the horizontal direction. The opening 352_G may be located above the waveguide 323 such that a portion of the waveguide 323 is exposed to the outside through the opening 352_G. In some embodiments, the waveguide 323 may further include a grating coupler 323_GC, wherein the grating coupler 323_GC may be located at a portion of the waveguide 323, which is exposed to the outside through the opening 352_G.

In some embodiments, an optical fiber F may be located inside the opening 352_G of the second molding layer 352. The optical fiber F may be located above the waveguide 323. For example, the optical fiber F may transmit and receive an optical signal to and from the waveguide 323. The optical fiber F may be optically connected to the waveguide 323 through the grating coupler 323_GC. In some embodiments, the optical fiber F may be a fiber array unit (FAU).

Referring back to FIG. 2, the semiconductor package 1000 may further include a third molding layer 400.

The third molding layer 400 may be located on the package substrate 100. The third molding layer 400 may surround the stacked structure 200 and the chip structure 300. For example, the third molding layer 400 may protect the stacked structure 200 and the chip structure 300 from the outside.

In some embodiments, the upper surface of the third molding layer 400 may be coplanar with the upper surface of each of the stacked structure 200 and the upper surface of the chip structure 300. For example, the upper surface of each of the stacked structure 200 and the upper surface of the chip structure 300 may be exposed to the outside.

In some embodiments, the third molding layer 400 may include an epoxy resin, a polyimide resin, or the like. The third molding layer 400 may include, for example an EMC.

In some embodiments, a boundary surface may be present between the first molding layer 351 and the third molding layer 400, and a boundary surface may be present between the second molding layer 352 and the third molding layer 400. For example, the boundary surface may be present between the first molding layer 351 and the third molding layer 400 and between the second molding layer 352 and the third molding layer 400 because curing times of the first molding layer 351, the second molding layer 352, and the third molding layer 400 are different from each other.

In some embodiments, the first molding layer 351, the second molding layer 352, and the third molding layer 400 may include the same material. However, even though the first molding layer 351, the second molding layer 352, and the third molding layer 400 include the same material, the boundary surface may be present between the first molding layer 351 and the third molding layer 400 and between the second molding layer 352 and the third molding layer 400.

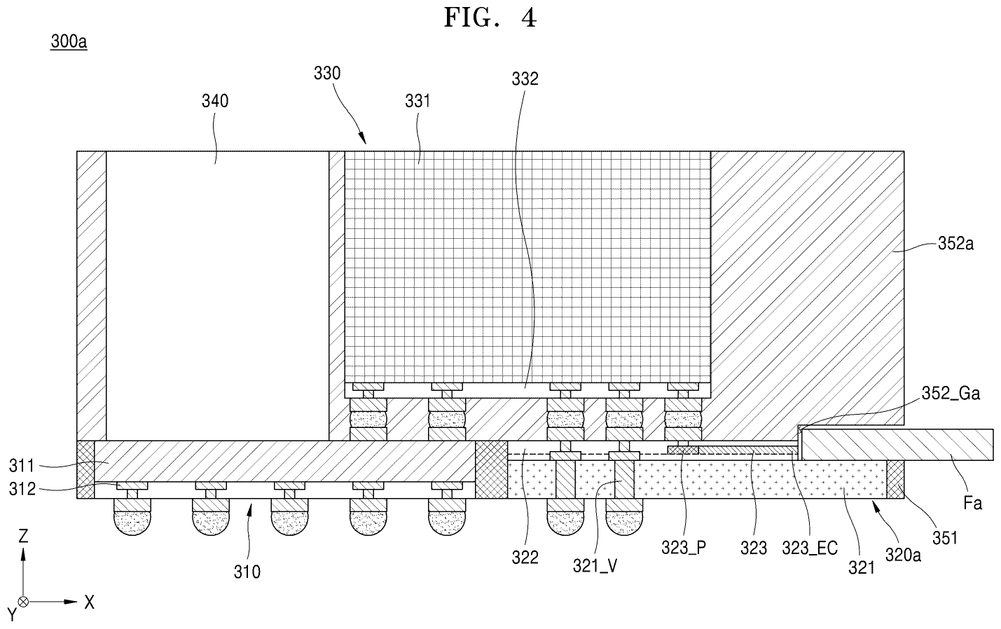

FIG. 4 is a magnified cross-sectional view schematically illustrating a chip structure 300a of a semiconductor package according to an embodiment.

Most elements constituting the chip structure 300a described below and materials forming the elements are substantially the same as or similar to those described above with reference to FIG. 3. Therefore, for convenience of description, differences between the chip structure 300a of FIG. 4 and the chip structure 300 of FIG. 3 described above are mainly described.

The chip structure 300a may include the semiconductor chip 310, a PIC chip 320a, the EIC chip 330, the first molding layer 351, and a second molding layer 352a. In some embodiments, the chip structure 300a may include a V-groove 352_Ga recessed inward from a side surface of the chip structure 300a. For example, the V-groove 352_Ga may be located in a second wiring structure 322 of the PIC chip 320a. However, the V-groove 352_Ga is not limited thereto and may be located in the second molding layer 352a and the second wiring structure 322 according to the depth of the V-groove 352_Ga in the vertical direction (the Z direction). Although not illustrated, the V-groove 352_Ga may be recessed inward from a side surface of a molding layer (e.g., similar to the third molding layer 400) which may surround the chip structure 300a.

An optical fiber Fa may be optically connected to the chip structure 300a through an edge coupler 323_EC. For example, the optical fiber Fa may be located inside the V-groove 352_Ga of the chip structure 300a such that the vertical level of the waveguide 323 is substantially the same as the vertical level of the optical fiber Fa. Because the optical fiber Fa is optically connected to the PIC chip 320a through the edge coupler 323_EC, the optical fiber Fa may transmit and receive a multi-wavelength optical signal to and from the PIC chip 320a.

The V-groove 352_Ga of the chip structure 300a may be recessed inward from a first side surface of the chip structure 300a. Accordingly, the stacked structure 200 may not be located at a side portion of the first side surface of the chip structure 300a.

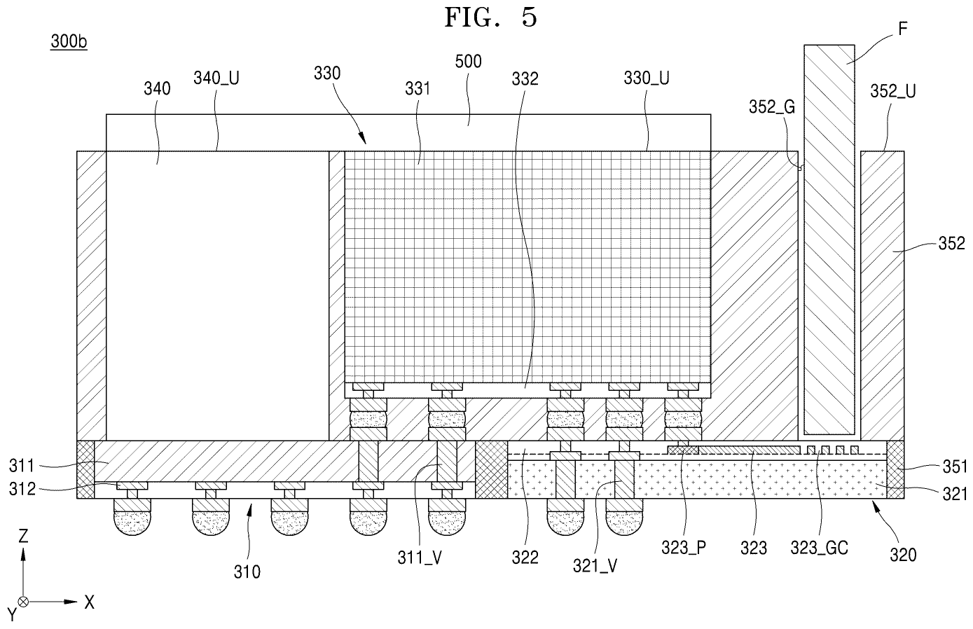

FIG. 5 is a magnified cross-sectional view schematically illustrating a chip structure 300b of a semiconductor package according to an embodiment.

Most elements constituting the chip structure 300b described below and materials forming the elements are substantially the same as or similar to those described above with reference to FIG. 3. Therefore, for convenience of description, differences between the chip structure 300b of FIG. 5 and the chip structure 300 of FIG. 3 described above are mainly described.

The chip structure 300b may further include a heat sink 500. The heat sink 500 may be located on the dummy chip 340 and/or the EIC chip 330. In some embodiments, the heat sink 500 may be in contact with the upper surface 340_U of the dummy chip 340 and the upper surface 330_U of the EIC chip 330.

The heat sink 500 may be configured to discharge heat generated by the semiconductor chip 310 and/or the EIC chip 330. The heat sink 500 may include a thermally conductive material having a high heat conductivity. For example, the heat sink 500 may include a metal, such as Cu or Al, or a carbon-containing material, such as graphene, graphite, and/or carbon nanotubes. However, a material of the heat sink 500 is not limited to the materials described above. In some embodiments, the heat sink 500 may include a single metal layer or a plurality of metal layers that are stacked.

In some embodiments, the heat sink 500 may be attached onto the dummy chip 340 and/or the EIC chip 330 through a thermal interface material (TIM) layer. Through contact with the dummy chip 340 and/or the EIC chip 330 through the TIM layer, the heat-dissipating characteristic of the heat sink 500 may be improved. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The TIM layer may include a thermally conductive and electrically insulating material. For example, the TIM layer may include a polymer including metal powder, such as Ag or Cu, thermal grease, white grease, or a combination thereof.

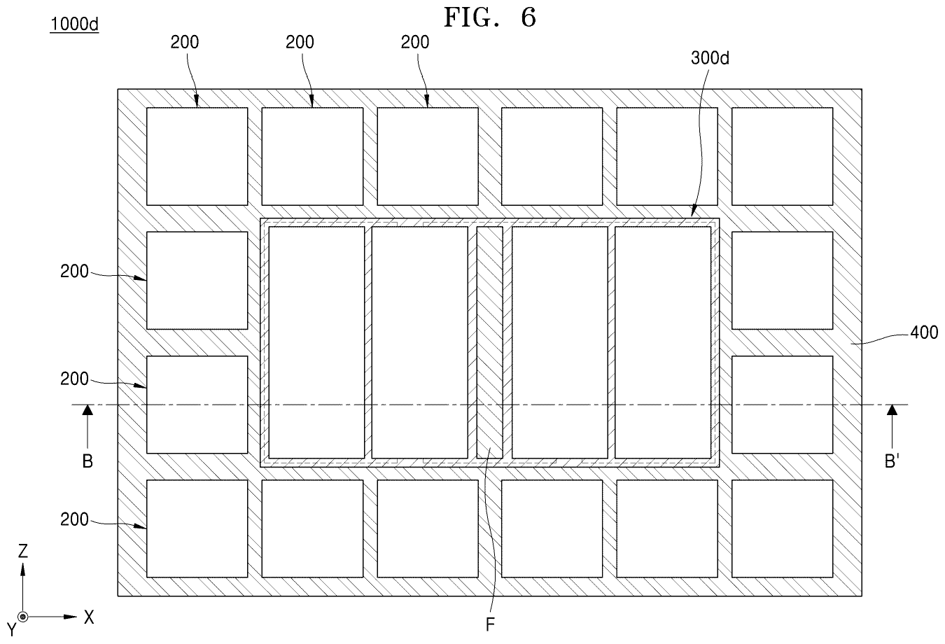

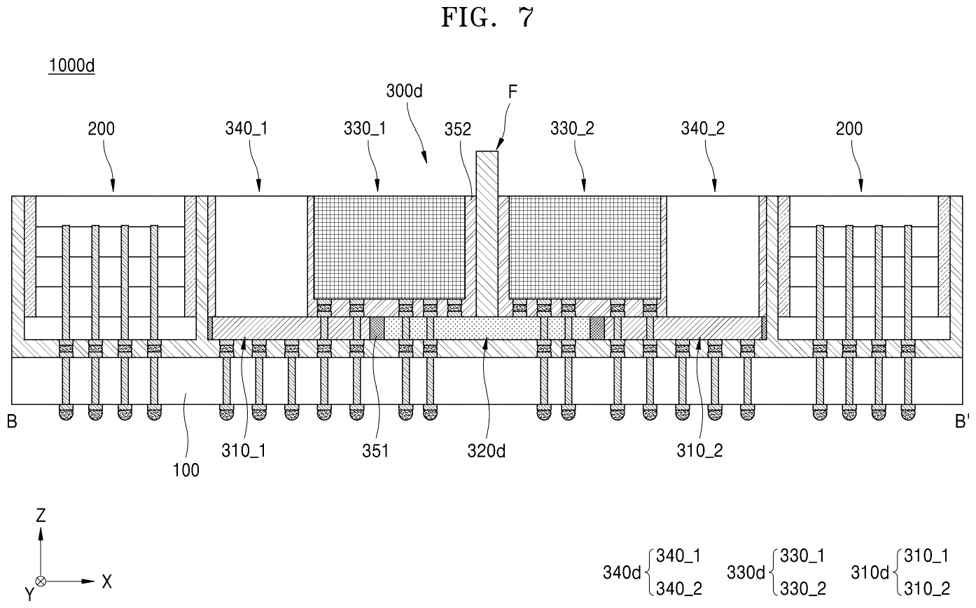

FIG. 6 is a top view schematically illustrating a semiconductor package 1000d according to an embodiment. FIG. 7 is a cross-sectional view schematically illustrating the semiconductor package 1000d of FIG. 6, taken along line B-B′ of FIG. 6.

Most elements constituting the semiconductor package 1000d described below and materials forming the elements are substantially the same as or similar to those described above with reference to FIG. 1. Therefore, for convenience of description, differences between the semiconductor package 1000d of FIG. 6 and the semiconductor package 1000 of FIG. 1 described above are mainly described.

The semiconductor package 1000d may include the package substrate 100, the stacked structure 200, and a chip structure 300d.

A plurality of stacked structures 200 may be disposed on the package substrate 100 to surround the chip structure 300d. For example, a plurality of stacked structures 200 may be arranged to form a quadrangular shape, and the chip structure 300d may be arranged in a region surrounded by the plurality of stacked structures 200. For example, the plurality of stacked structures 200 may be located in an edge region of the package substrate 100, and the chip structure 300d may be located in a central region of the package substrate 100.

The chip structure 300d may include a PIC chip 320d, a plurality of EIC chips 330d, and a plurality of semiconductor chips 310d. The plurality of semiconductor chips 310d may be spaced apart from the PIC chip 320d in the horizontal direction. The plurality of EIC chips 330d may be located on the PIC chip 320d. For example, a portion of each of the plurality of EIC chips 330d may overlap the PIC chip 320d in the vertical direction (the Z direction), and another portion thereof may overlap one of the plurality of semiconductor chips 310d in the vertical direction (the Z direction).

In some embodiments, the plurality of semiconductor chips 310d may include a first semiconductor chip 310_1 and a second semiconductor chip 310_2. The plurality of EIC chips 330d may include a first EIC chip 330_1 and a second EIC chip 330_2. However, the numbers of semiconductor chips 310d and EIC chips 330d are not limited thereto.

In some embodiments, the first semiconductor chip 310_1 may be spaced apart from the second semiconductor chip 3102 with the PIC chip 320d disposed therebetween. A stacked structure 200 configured to transmit and receive a signal to and from the first semiconductor chip 310_1 among the plurality of stacked structures 200 may differ from a stacked structure 200 configured to transmit and receive a signal to and from the second semiconductor chip 310_2 among the plurality of stacked structures 200. For example, the stacked structure 200 configured to transmit and receive a signal to and from the first semiconductor chip 310_1 among the plurality of stacked structures 200 may be adjacent to the first semiconductor chip 310_1, and the stacked structure 200 configured to transmit and receive a signal to and from the second semiconductor chip 310_2 among the plurality of stacked structures 200 may be adjacent to the second semiconductor chip 3102.

The first EIC chip 3301 may be spaced apart from the second EIC chip 330_2 in the horizontal direction. For example, a portion of the first EIC chip 330_1 may overlap the PIC chip 320d in the vertical direction (the Z direction), and another portion of the first EIC chip 3301 may overlap the first semiconductor chip 310_1 in the vertical direction (the Z direction). A portion of the second EIC chip 3302 may overlap the PIC chip 320d in the vertical direction (the Z direction), and another portion of the second EIC chip 330_2 may overlap the second semiconductor chip 310_2 in the vertical direction (the Z direction). In some embodiments, the optical fiber F may be disposed between the first EIC chip 330_1 and the second EIC chip 3302.

In some embodiments, the semiconductor package 1000d may further include a plurality of dummy chips 340d. The plurality of dummy chips 340d may include a first dummy chip 340_1 and a second dummy chip 3402. The first dummy chip 3401 may be located on the first semiconductor chip 310_1, and the second dummy chip 3402 may be located on the second semiconductor chip 3102.

Relative to other semiconductor packages, the semiconductor package 1000d may include an increased number of stacked structures 200 by electrically connecting one PIC chip 320d to the plurality of semiconductor chips 310d. Accordingly, the semiconductor package 1000d may have an increased bandwidth and an increased data processing speed.

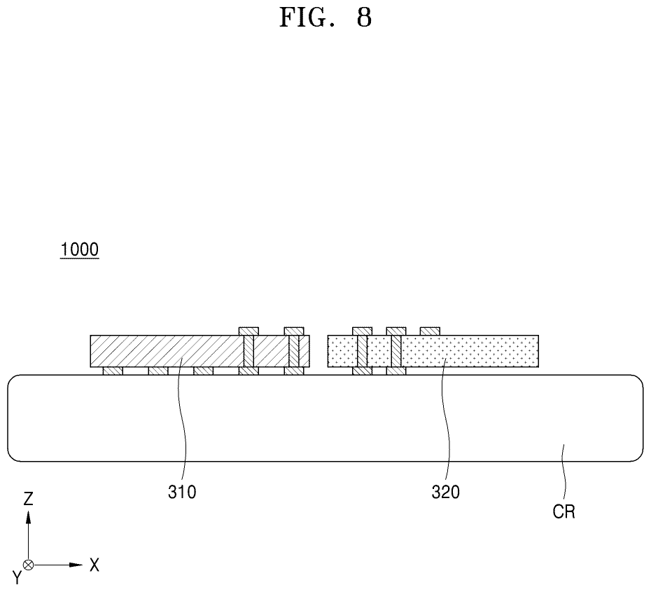

FIGS. 8 to 14 are cross-sectional views illustrating, in a process order, a method of manufacturing a semiconductor package, according to an embodiment.

Particularly, FIGS. 8 to 14 are cross-sectional views illustrating, in an order, a process of manufacturing the semiconductor package 1000 of FIG. 1, taken along line A-A′ of FIG. 1. In particular, FIGS. 8 to 11 are cross-sectional views illustrating, in an order, a process of manufacturing the chip structure 300 of the semiconductor package 1000 of FIG. 1.

Most elements constituting the semiconductor package 1000 described below and materials forming the elements are substantially the same as or similar to those described above with reference to FIG. 1. Therefore, for convenience of description, the description made for the semiconductor package 1000 of FIG. 1 is omitted herein.

Referring to FIG. 8, the semiconductor chip 310 and the PIC chip 320 may be attached onto a carrier substrate CR through an adhesive insulating layer (not shown).

The carrier substrate CR may include, for example, glass, Si, or Al oxide. The adhesive insulating layer may include an arbitrary material which fixes the package substrate 100. The adhesive insulating layer may be, for example, an adhesive tape of which the adhesive strength is weakened by heat treatment or laser irradiation.

The PIC chip 320 may be spaced apart from the semiconductor chip 310 in the horizontal direction. In some embodiments, the semiconductor chip 310 may have the same thickness (i.e., length in the vertical direction) as the PIC chip 320.

For example, the semiconductor chip 310 may be arranged such that an active surface of the semiconductor chip 310 faces downward, and the PIC chip 320 may be arranged such that a waveguide of the PIC chip 320 faces upward. For example, the semiconductor chip 310 may be arranged in the face down manner, and the PIC chip 320 may be arranged in a face up manner.

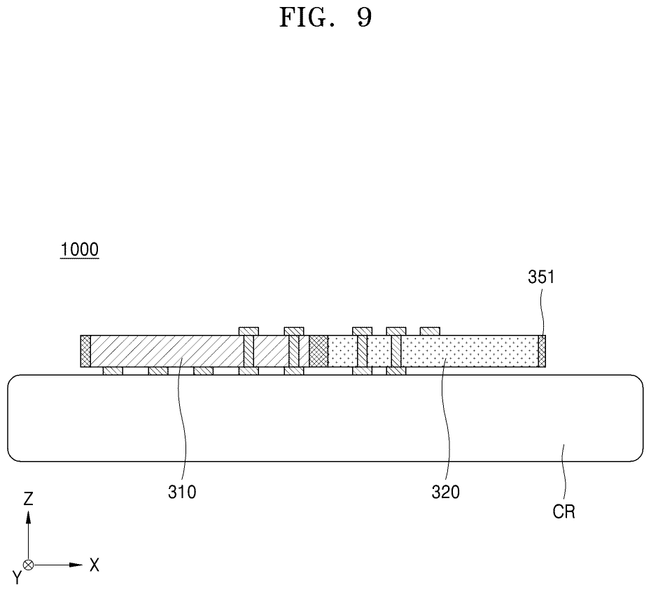

Referring to FIG. 9, the first molding layer 351 surrounding the semiconductor chip 310 and the PIC chip 320 may be formed.

After forming the first molding layer 351 such that the first molding layer 351 covers the semiconductor chip 310 and the PIC chip 320, a portion of the first molding layer 351 may be removed such that the upper surfaces of the semiconductor chip 310 and the PIC chip 320 are exposed to the outside. The first molding layer 351 may protect the semiconductor chip 310 and the PIC chip 320 from the outside.

In some embodiments, the lower surface of the first molding layer 351, the lower surface of the semiconductor chip 310, and the lower surface of the PIC chip 320 may be coplanar with each other. In some embodiments, the upper surface 351_U (see FIG. 3) of the first molding layer 351, the upper surface of the semiconductor chip 310, and the upper surface of the PIC chip 320 may be coplanar with each other. For example, the first molding layer 351, the semiconductor chip 310, and the PIC chip 320 may have the same thickness.

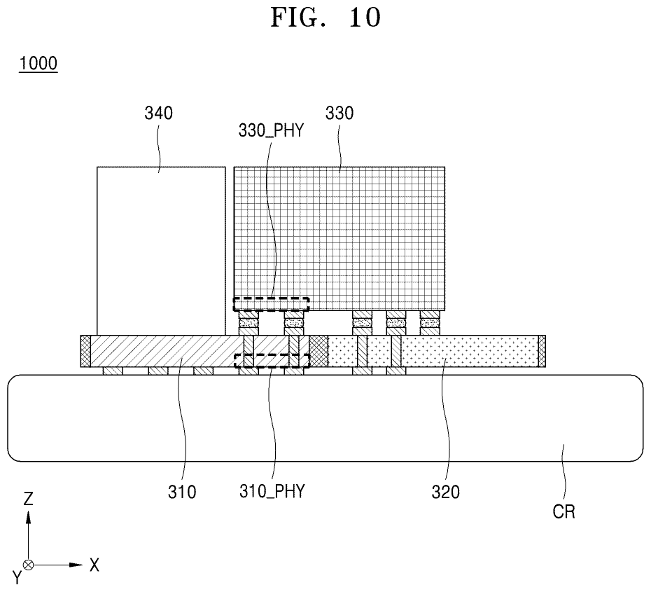

Referring to FIG. 10, the EIC chip 330 and the dummy chip 340 may be mounted on the result of FIG. 9.

The EIC chip 330 may be mounted on the semiconductor chip 310 and the PIC chip 320. For example, a portion of the EIC chip 330 may overlap the semiconductor chip 310 in the vertical direction (the Z direction), and another portion of the EIC chip 330 may overlap the PIC chip 320 in the vertical direction (the Z direction).

In some embodiments, the physical layer 330_PHY of the EIC chip 330 may overlap the physical layer 310_PHY of the semiconductor chip 310 in the vertical direction (the Z direction). In some embodiments, the EIC chip 330 may overlap the first through vias 311_V (see FIG. 3) of the semiconductor chip 310 and the second through vias 321_V (see FIG. 3) of the PIC chip 320 in the vertical direction (the Z direction). For example, the first through vias 311_V (see FIG. 3) and the second through vias 321_V (see FIG. 3) may be under the EIC chip 330.

The dummy chip 340 may be located on the semiconductor chip 310. The dummy chip 340 may be spaced apart from the EIC chip 330 in the horizontal direction. In some embodiments, the dummy chip 340 may be attached onto the semiconductor chip 310 by direct bonding or an adhesive member.

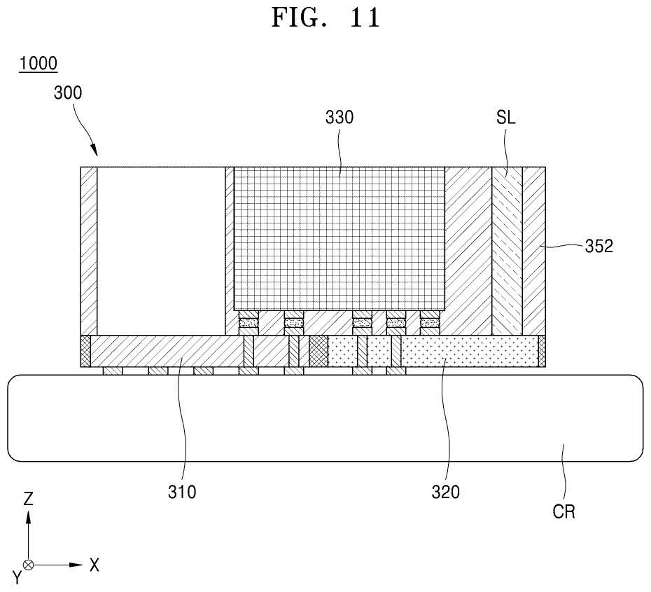

Referring to FIG. 11, the second molding layer 352 surrounding the EIC chip 330 and the dummy chip 340 may be formed.

After forming the second molding layer 352 such that the second molding layer 352 covers the EIC chip 330 and the dummy chip 340, a portion of the second molding layer 352 may be removed such that the upper surfaces of the EIC chip 330 and the dummy chip 340 are exposed to the outside. The second molding layer 352 may protect the EIC chip 330 and the dummy chip 340 from the outside.

In some embodiments, the upper surface of the second molding layer 352, the upper surface of the EIC chip 330, and the upper surface of the dummy chip 340 may be coplanar with each other. For example, the second molding layer 352, the EIC chip 330, and the dummy chip 340 may have the same thickness.

A boundary surface may be present between the first molding layer 351 and the second molding layer 352 because a curing time of the first molding layer 351 differs from a curing time of the second molding layer 352. For example, the boundary surface may be present between the first molding layer 351 and the second molding layer 352 even though the first molding layer 351 includes the same material as the second molding layer 352.

In some embodiments, a sacrificial layer SL penetrating the second molding layer 352 may be formed. For example, the sacrificial layer SL may be located above the waveguide of the PIC chip 320.

In some embodiments, the result of FIG. 11 may be tested. For example, it may be tested whether an electrical connection of the PIC chip 320, the EIC chip 330, and the semiconductor chip 310 is normal. That is, whether the chip structure 300 is normal may be tested in advance before the chip structure 300 is mounted on the package substrate 100, thereby improving a yield of the semiconductor package 1000.

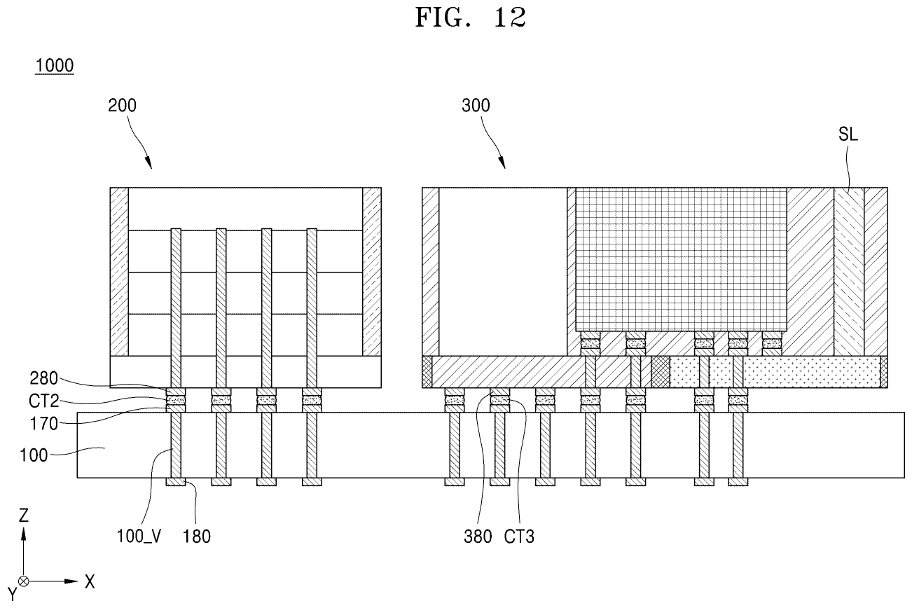

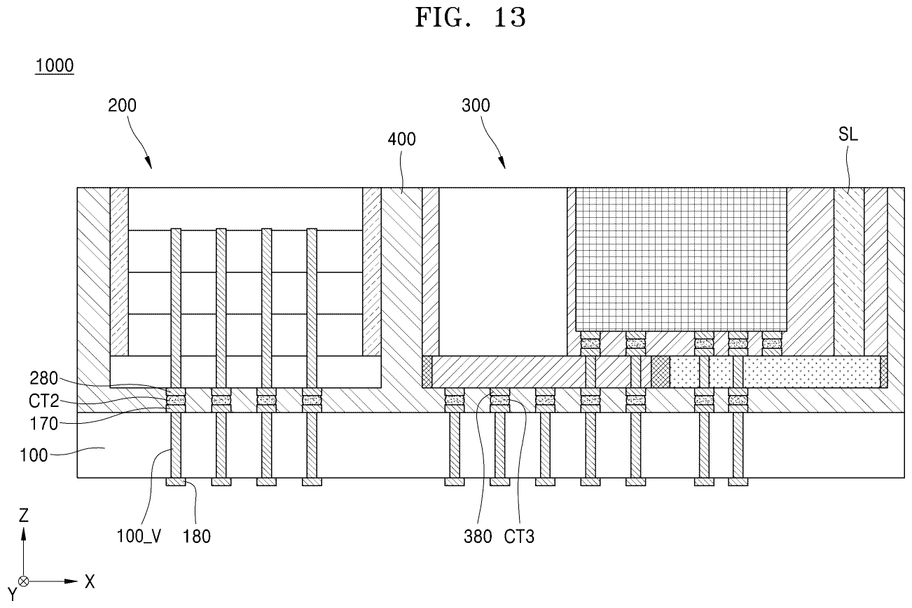

Referring to FIGS. 12 and 13, after mounting on the package substrate 100 the at least one stacked structure 200 and the chip structure 300 that is the result of FIG. 11, the third molding layer 400 may be formed.

The package substrate 100 may be an Si interposer, a glass interposer, or a PCB.

The stacked structure 200 and the chip structure 300 may be disposed on the package substrate 100 so as to be spaced apart from each other in the horizontal direction. For example, a plurality of stacked structures 200 may be arranged to surround the chip structure 300.

In some embodiments, each of the stacked structure 200 and the chip structure 300 may be electrically connected to the package substrate 100 through the connection terminals CT2 and CT3. However, each of the stacked structure 200 and the chip structure 300 is not limited thereto and may be electrically connected to the package substrate 100 by an ACF, an NCF, direct bonding, or hybrid bonding.

Next, after forming the third molding layer 400 such that the third molding layer 400 covers the stacked structure 200 and the chip structure 300, a portion of the third molding layer 400 may be removed such that the upper surfaces of the stacked structure 200 and the chip structure 300 are exposed to the outside. The third molding layer 400 may protect the stacked structure 200 and the chip structure 300 from the outside.

A boundary surface may be present between the first molding layer 351 and the third molding layer 400 and between the second molding layer 352 and the third molding layer 400 because curing times of the first molding layer 351, the second molding layer 352, and the third molding layer 400 are different from each other. For example, even though the first molding layer 351, the second molding layer 352, and the third molding layer 400 include the same material, the boundary surface may be present between the first molding layer 351 and the third molding layer 400 and between the second molding layer 352 and the third molding layer 400.

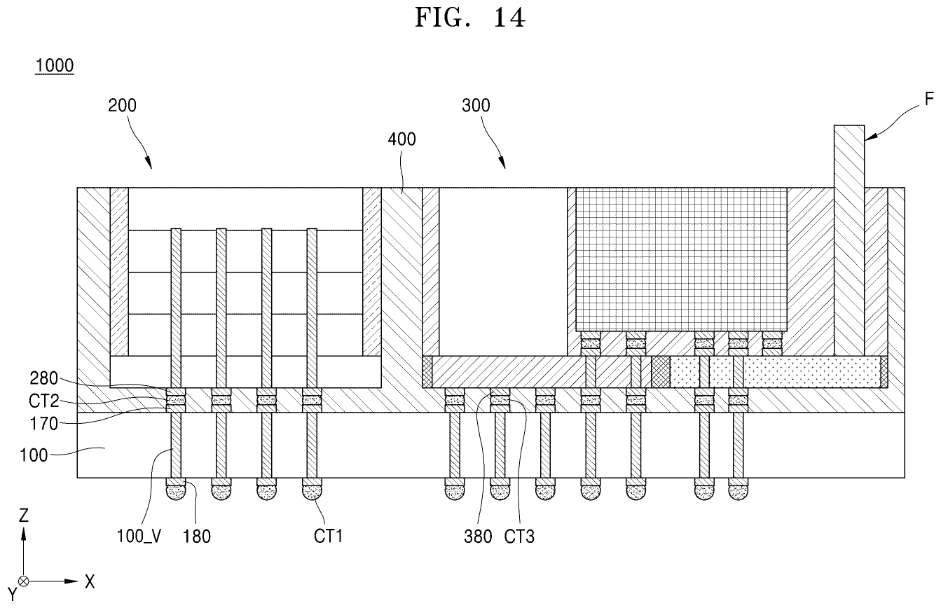

Referring to FIG. 14, the sacrificial layer SL may be removed, and the optical fiber F may be attached to the chip structure 300.

The sacrificial layer SL may be removed to form an opening in the second molding layer 352 of the chip structure 300. Accordingly, a portion of the waveguide 323 of the PIC chip 320 may be exposed to the outside. The optical fiber F may be attached to the inside of the opening of the second molding layer 352. One end portion of the optical fiber F may face the PIC chip 320 and be optically connected to the waveguide 323 of the PIC chip 320.

The external connection terminals CT1 may be attached to the lower pads 180 of the package substrate 100. In some embodiments, the external connection terminals CT1 may include, for example, a solder ball, a conductive bump, a conductive paste, a ball grid array (BGA), or a combination thereof.

While aspects of the inventive concept have been particularly shown and described with reference to embodiments thereof, it will be understood that various changes in form and details may be made therein without departing from the spirit and scope of the following claims.

What is claimed is:

1. A chip structure comprising:
a semiconductor chip;
a photonic integrated circuit chip spaced apart from the semiconductor chip in a horizontal direction;
an electronic integrated circuit chip on the semiconductor chip and the photonic integrated circuit chip;
a first molding layer surrounding the semiconductor chip and the photonic integrated circuit chip; and
a second molding layer on the semiconductor chip, the photonic integrated circuit chip, and the first molding layer and surrounding the electronic integrated circuit chip,
wherein a portion of the electronic integrated circuit chip overlaps the photonic integrated circuit chip in a vertical direction, and another portion of the electronic integrated circuit chip overlaps the semiconductor chip in the vertical direction.

2. The chip structure of claim 1, wherein the semiconductor chip further comprises an active surface and an inactive surface opposite to the active surface, the photonic integrated circuit chip further comprises a waveguide, and a vertical level of the active surface of the semiconductor chip is lower than a vertical level of the waveguide of the photonic integrated circuit chip.

3. The chip structure of claim 1, wherein a physical layer of the electronic integrated circuit chip overlaps a physical layer of the semiconductor chip in the vertical direction.

4. The chip structure of claim 1, wherein the semiconductor chip further comprises a first through via, the photonic integrated circuit chip further comprises a second through via, and the first through via and the second through via overlap the electronic integrated circuit chip in the vertical direction.

5. The chip structure of claim 1, wherein a boundary surface is present between the first molding layer and the second molding layer.

6. The chip structure of claim 5, wherein an upper surface of the first molding layer is coplanar with an upper surface of the photonic integrated circuit chip and an upper surface of the semiconductor chip.

7. The chip structure of claim 1, further comprising a dummy chip on the semiconductor chip,
wherein the second molding layer surrounds the dummy chip and the electronic integrated circuit chip.

8. The chip structure of claim 7, wherein an upper surface of the second molding layer is coplanar with upper surfaces of the dummy chip and the electronic integrated circuit chip.

9. The chip structure of claim 1, wherein the second molding layer comprises an opening extending inward from an upper surface of the second molding layer, and the opening is located above a waveguide of the photonic integrated circuit chip and spaced apart from the electronic integrated circuit chip in the horizontal direction.

10. A semiconductor package comprising:
a package substrate;
at least one stacked structure on the package substrate; and
a chip structure on the package substrate and spaced apart from the at least one stacked structure in a horizontal direction,
wherein the chip structure comprises:
a semiconductor chip on the package substrate;
a photonic integrated circuit chip on the package substrate and spaced apart from the semiconductor chip in the horizontal direction;
an electronic integrated circuit chip on the semiconductor chip and the photonic integrated circuit chip;
a first molding layer surrounding the semiconductor chip and the photonic integrated circuit chip; and
a second molding layer on the first molding layer and surrounding the electronic integrated circuit chip,
wherein a portion of the electronic integrated circuit chip overlaps the photonic integrated circuit chip in a vertical direction, and another portion of the electronic integrated circuit chip overlaps the semiconductor chip in the vertical direction.

11. The semiconductor package of claim 10, further comprising a third molding layer on the package substrate and surrounding the at least one stacked structure and the chip structure.

12. The semiconductor package of claim 11, wherein a boundary surface is present between the third molding layer and the first molding layer, and a boundary surface is present between the third molding layer and the second molding layer.

13. The semiconductor package of claim 12, wherein the first molding layer, the second molding layer, and the third molding layer include the same material.

14. The semiconductor package of claim 10, wherein the stacked structure comprises a buffer chip and a plurality of core chips stacked on the buffer chip.

15. The semiconductor package of claim 10, wherein the chip structure further comprises a dummy chip,
wherein the dummy chip is on the semiconductor chip and spaced apart from the electronic integrated circuit chip.

16. The semiconductor package of claim 10, wherein a plurality of stacked structures are provided on the package substrate, an area of each of the plurality of stacked structures is less than an area of the chip structure, and the plurality of stacked structures are arranged to surround the chip structure.

17. The semiconductor package of claim 10, wherein the semiconductor chip of the chip structure further comprises an active surface and an inactive surface opposite to the active surface, the photonic integrated circuit chip of the chip structure further comprises a waveguide, the active surface of the semiconductor chip faces the package substrate, and the waveguide of the photonic integrated circuit chip faces the electronic integrated circuit chip.

18. A semiconductor package comprising:
a package substrate;
a plurality of stacked structures on the package substrate;
a chip structure on the package substrate and spaced apart from the plurality of stacked structures in a horizontal direction; and
a third molding layer on the package substrate and surrounding the plurality of stacked structures and the chip structure,
wherein the chip structure comprises:
a semiconductor chip on the package substrate and comprising a first through via;
a photonic integrated circuit chip on the package substrate, spaced apart from the semiconductor chip in the horizontal direction, and comprising a second through via;
an electronic integrated circuit chip on the semiconductor chip and the photonic integrated circuit chip;
a dummy chip on the semiconductor chip;
a first molding layer surrounding the semiconductor chip and the photonic integrated circuit chip; and
a second molding layer on the first molding layer and surrounding the electronic integrated circuit chip and the dummy chip,
wherein a portion of the electronic integrated circuit chip overlaps the second through via of the photonic integrated circuit chip in a vertical direction, and another portion of the electronic integrated circuit chip overlaps the first through via of the semiconductor chip in the vertical direction.

19. The semiconductor package of claim 18, wherein a boundary surface is present between the first molding layer and the second molding layer, and a boundary surface is present between the second molding layer and the third molding layer.

20. The semiconductor package of claim 18, wherein the semiconductor chip further comprises an active surface and an inactive surface opposite to the active surface, the photonic integrated circuit chip further comprises a waveguide, and a vertical level of the active surface of the semiconductor chip is lower than a vertical level of the waveguide of the photonic integrated circuit chip.
